(19) United States
(12) Patent Application Publication
(10) Pub. No.: US 2024/0079295 A1
(43) Pub. Date: Mar. 7, 2024

(54) TALL POWER LINES WITH ALIGNED SIGNAL WIRES

(71) Applicant: INTERNATIONAL BUSINESS MACHINES CORPORATION, Armonk, NY (US)

(72) Inventors: Ruilong Xie, Niskayuna, NY (US); Nicholas Anthony Lanzillo, Wynantskill, NY (US); Hosadurga Shobha, Niskayuna, NY (US); Huai Huang, Clifton Park, NY (US); Lawrence A Clevenger, Saratoga Springs, NY (US)

(21) Appl. No.: 17/902,471

(22) Filed: Sep. 2, 2022

(51) Int. Cl. H01L 23/48; H01L 21/768

(52) U.S. Cl. CPC H01L 23/481; H01L 21/76879

(57) ABSTRACT

Devices and methods of forming the same include a first conductive line having a top surface at a first height above an underlying layer. A second conductive line, parallel to the first conductive line, has a second height above the underlying layer that is greater than the first height. A first interlayer dielectric layer, between the first conductive line and the second conductive line, has a top surface at a third height above the underlying layer that is greater than the first height and that is less than the second height.

### BACKGROUND

The present invention generally relates to integrated chip fabrication, and, more particularly, to fabrication of power and signal lines in an integrated chip.

As lithographic feature size decreases, so too does the cross-sectional area of power-carrying lines in an integrated chip. The resistance of wires increases inversely proportional to the cross-sectional area of the power-carrying lines. Thus, reducing the feature size of power-carrying lines, which may travel over significant distances on the integrated chip, can substantially increase power dissipation in the chip as waste heat.

### SUMMARY

A device includes a first conductive line having a top surface at a first height above an underlying layer. A second conductive line, parallel to the first conductive line, has a second height above the underlying layer that is greater than the first height. A first interlayer dielectric layer, between the first conductive line and the second conductive line, has a top surface at a third height above the underlying layer that is greater than the first height and that is no greater than the second height.

A device includes a first conductive line having first width and a top surface at a first height above an underlying layer. A second conductive line, parallel to the first conductive line, has a second width that is greater than the first width and has a curved top surface with a second height above the underlying layer that is greater than the first height. A first interlayer dielectric layer, formed from a first dielectric material, between the first conductive line and the second conductive line, has a top surface at a third height above the underlying layer that is between the first height and the second height. A dielectric cap over the first conductive line is formed from a second dielectric material that is different from the first dielectric material, the second conductive line, and the first interlayer dielectric layer. A third conductive line over the first conductive line and the second conductive line is oriented perpendicular relative to the first conductive line and the second conductive line. A conductive via extends through the dielectric cap to make electrical contact between the first conductive line and the third conductive line.

A method of forming a device includes etching a first trench and a second trench into a dielectric layer. A conductive material is deposited in the first trench and the second trench. A dielectric cap is formed over the first trench, leaving the second trench exposed. Additional conductive material is selectively deposited in the second trench.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a cross-sectional diagram of a step in the fabrication of a device having power-carrying lines and signal-carrying lines that have different respective heights, showing a layer of dielectric material over an underlying layer, in accordance with an embodiment of the present invention;

FIG. 2 is a cross-sectional diagram of a step in the fabrication of a device having power-carrying lines and signal-carrying lines that have different respective heights, showing the formation of power line trenches and signal line trenches in the dielectric layer, in accordance with an embodiment of the present invention;

FIG. 3 is a cross-sectional diagram of a step in the fabrication of a device having power-carrying lines and signal-carrying lines that have different respective heights, showing the deposition of conductive material in the power line trenches and the signal line trenches, in accordance with an embodiment of the present invention;

FIG. 4 is a cross-sectional diagram of a step in the fabrication of a device having power-carrying lines and signal-carrying lines that have different respective heights, showing an isotropic recess of the conductive material in the trenches, in accordance with an embodiment of the present invention;

FIG. 5 is a cross-sectional diagram of a step in the fabrication of a device having power-carrying lines and signal-carrying lines that have different respective heights, showing the conformal deposition of dielectric capping material over the trenches, in accordance with an embodiment of the present invention;

FIG. 6 is a cross-sectional diagram of a step in the fabrication of a device having power-carrying lines and signal-carrying lines that have different respective heights, showing an isotropic etch of the dielectric capping material that exposes the conductive material in the power line trenches, in accordance with an embodiment of the present invention;

FIG. 7 is a cross-sectional diagram of a step in the fabrication of a device having power-carrying lines and signal-carrying lines that have different respective heights, showing the selective deposition of conductive material in the power line trenches, in accordance with an embodiment of the present invention;

FIG. 8 is a cross-sectional diagram of a step in the fabrication of a device having power-carrying lines and signal-carrying lines that have different respective heights, showing the formation of a dielectric cap over the signal lines and the power lines, in accordance with an embodiment of the present invention;

FIG. 9 is a cross-sectional diagram of a step in the fabrication of a device having power-carrying lines and signal-carrying lines that have different respective heights, showing the formation of a dielectric layer over the signal lines and power lines that has a trench and a via over a signal line, in accordance with an embodiment of the present invention;

FIG. 10 is a cross-sectional diagram of a step in the fabrication of a device having power-carrying lines and signal-carrying lines that have different respective heights, showing the formation of a via through the dielectric cap that exposes a signal line, in accordance with an embodiment of the present invention;

FIG. 11 is a cross-sectional diagram of a step in the fabrication of a device having power-carrying lines and signal-carrying lines that have different respective heights, showing the formation of a conductive line and conductive via over the exposed signal line, in accordance with an embodiment of the present invention; and

FIG. 12 is a block/flow diagram of a method of forming a device that has power-carrying lines and signal-carrying lines with different respective heights, in accordance with an embodiment of the present invention.

### DETAILED DESCRIPTION

As chip feature size decreases, and the width of power-carrying lines decreases with it, the resistance of these lines increases. This increase of resistance leads to increased power losses, as electrical energy dissipates as heat. These power losses decrease the efficiency of the device, while the increased heat dissipation can diminish device performance or even damage the device if not controlled.

To decrease the resistance of power-carrying lines in an integrated chip, even when fabricating devices with small feature sizes (e.g., 2 nm or less), the height of the power-carrying lines may be increased. The increased height increases the cross-sectional area of the power-carrying lines without sacrificing areal density on the chip. Thus, an increase in the height of the power-carrying lines decreases the resistance of the power-carrying lines without decreasing the number of lines that can be fit onto a chip. In some examples, the increased height of the power-carrying lines can decrease line resistance by between about 10% and 40%. This is of particular note for power-carrying lines, which may have longer run lengths than signal-carrying lines. Thus, an increase in size of the power-carrying lines can provide substantial improvements to the electrical characteristics of the device, whereas signal-carrying lines may be kept relatively short.

At the same time, however, tight-pitch interconnects below 30 nm benefit from fully-aligned vias, as the close spacing between structures increases the risk of unintended shorting between lines and vias. Additionally, dielectric breakdown between lines and vias is a concern, and depends on the minimum distance between the metals. As described in greater detail below, the height of the power-carrying lines can be increased without increasing the height of the signal lines, while keeping the relatively short signal lines fully aligned with the vias that provide signal communication between metallization layers.

Referring now to FIG. 1, a cross-sectional view of a step in the fabrication of an integrated chip is shown. An underlying layer 102 is provided, and an interlayer dielectric 104 is deposited on top of the underlying layer 102. The underlying layer 102 may be any appropriate substrate or device. For example, the underlying layer 102 may be a semiconductor substrate. In some cases, the underlying layer 102 may itself be an integrated chip formed from one or more layers of devices and interconnects. The underlying layer 102 may have a top surface with exposed electrical contacts, which may make electrical contact with power-carrying lines and signal lines on overlying metallization layers.

Thus, in some embodiments, the underlying layer 102 may include, for example, transistors and other active and passive circuit components. The devices in the underlying layer 102 may need access to power and signal communications and so may have appropriate contacts that reach to the surface of the underlying layer 102. Thus power-carrying lines and signal lines may be formed within the interlayer dielectric 104 that make contact with the underlying layer 102.

In some embodiments, the underlying layer 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the underlying layer 102 may also be a semiconductor on insulator (SOI) substrate.

The interlayer dielectric 104 may be formed from, e.g., silicon dioxide or any other appropriate dielectric material. The dielectric material may be deposited using any appropriate process including, e.g., chemical vapor deposition (CVD), physical vapor deposition (PVD), atomic layer deposition (ALD), or gas cluster ion beam (GCIB) deposition. CVD is a deposition process in which a deposited species is formed as a result of chemical reaction between gaseous reactants at greater than room temperature (e.g., from about 25° C. about 900° C.). The solid product of the reaction is deposited on the surface on which a film, coating, or layer of the solid product is to be formed. Variations of CVD processes include, but are not limited to, Atmospheric Pressure CVD (APCVD), Low Pressure CVD (LPCVD), Plasma Enhanced CVD (PECVD), and Metal-Organic CVD (MOCVD) and combinations thereof may also be employed. In alternative embodiments that use PVD, a sputtering apparatus may include direct-current diode systems, radio frequency sputtering, magnetron sputtering, or ionized metal plasma sputtering. In alternative embodiments that use ALD, chemical precursors react with the surface of a material one at a time to deposit a thin film on the surface. In alternative embodiments that use GCIB deposition, a high-pressure gas is allowed to expand in a vacuum, subsequently condensing into clusters. The clusters can be ionized and directed onto a surface, providing a highly anisotropic deposition.

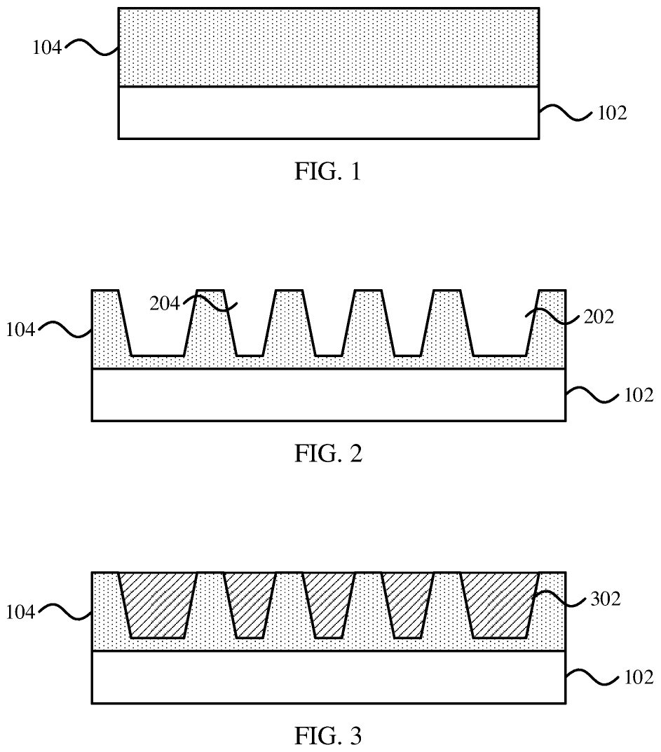

Referring now to FIG. 2, a cross-sectional view of a step in the fabrication of an integrated chip is shown. Trenches are etched into the interlayer dielectric 104, including power line trenches 202 and signal line trenches 204. The power line trenches 202 may be wider than the signal line trenches 204. The trenches may be formed using any appropriate process, including a photolithographic process.

Although the power line trenches 202 and the signal line trenches 204 are shown as being separated from the underlying layer 102, it should be understood that they may penetrate down to the surface of the underlying layer 102. In some embodiments, vias may be formed to the underlying layer 102 from the power line trenches 202 and the signal line trenches 204, so that lines formed in these trenches may make electrical contact with devices or transmission lines within the underlying layer. In some embodiments, the power line trenches 202 and the signal line trenches 204 may fully penetrate the interlayer dielectric 104.

In a photolithographic process, a pattern may be produced by applying a photoresist to the surface to be etched. The photoresist may be exposed to a pattern of radiation that defines regions to be protected and regions to be exposed. The pattern may be developed into the photoresist utilizing a resist developer, which may remove portions of the photoresist in regions that are to be exposed, creating a mask. Once the patterning of the photoresist is completed, the sections covered by the mask are protected while the exposed regions are removed using a selective etching process that removes the unprotected regions.

Reactive Ion Etching (RIE) is a form of plasma etching that can be used to anisotropically etch the interlayer dielectric 104 to produce the trenches. In RIE, the surface to be etched is placed on a radio-frequency powered electrode. The surface to be etched takes on a potential that accelerates the etching species extracted from plasma toward the surface, in which the chemical etching reaction is taking place in the direction normal to the surface. Other examples of anisotropic etching that can be used at this point of the present invention include ion beam etching, plasma etching or laser ablation.

The RIE is a directional etch that selectively removes material from the interlayer dielectric 104 without damaging the photolithographic mask. As used herein, the term “selective” in reference to a material removal process denotes that the rate of material removal for a first material is greater than the rate of removal for at least another material of the structure to which the material removal process is being applied.

Referring now to FIG. 3, a cross-sectional view of a step in the fabrication of an integrated chip is shown. Conductive material 302 is deposited using any conformal deposition process to fill the trenches. Excess conductive material may be removed from top surfaces of the interlayer dielectric 104 after deposition using a chemical planarization (CMP) process.

In embodiments where a via penetrates the remaining interlayer dielectric 104 between the power line trenches 202 or the signal line trenches 202 and the underlying layer 102, the conductive material 302 may fill that via to make electrical contact with the underlying layer 102. Thus, if a device of the underlying layer 102 includes a conductive contact that reaches to the top surface of the underlying layer 102, then the conductive material 302 may form an electrical connection to that device, providing power or signal communications.

CMP is performed using, e.g., a chemical or granular slurry and mechanical force to gradually remove upper layers of the device. The slurry may be formulated to be unable to dissolve, for example, the interlayer dielectric material, resulting in the CMP process's inability to proceed any farther than that layer.

The conductive material 302 may include any appropriate conductive metal such as, e.g., tungsten, nickel, titanium, molybdenum, tantalum, copper, platinum, silver, gold, ruthenium, iridium, rhenium, rhodium, cobalt, and alloys thereof. The conductive material 302 may alternatively be formed from a doped semiconductor material such as, e.g., doped polysilicon.

Prior to the deposition of the conductive material 302, a liner of barrier material (not shown) may be deposited on surfaces of the trenches 202 and 204. The barrier material serves to inhibit diffusion of the conductive material 302 into the material of the interlayer dielectric 104, which could otherwise result in leakage current and a loss of efficiency.

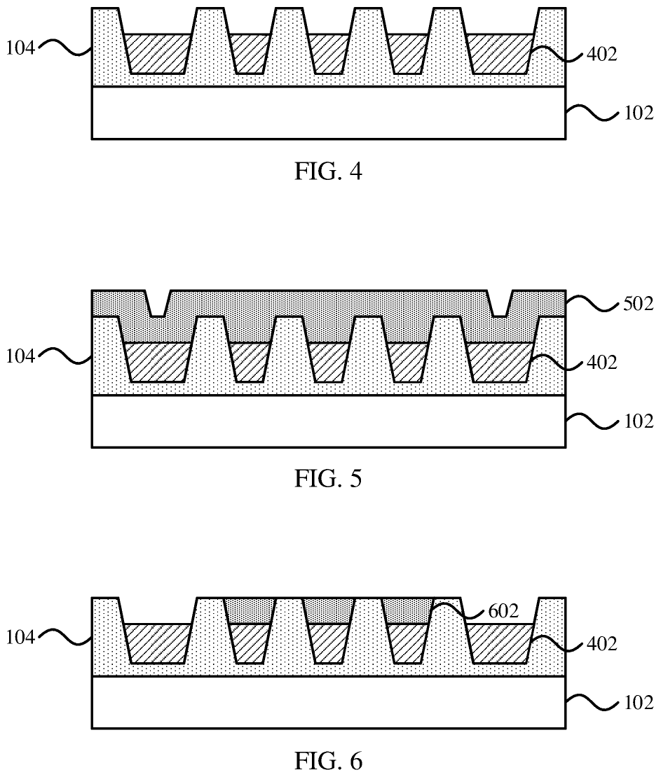

Referring now to FIG. 4, a cross-sectional view of a step in the fabrication of an integrated chip is shown. The conductive material 302 may be etched back using any appropriate selective isotropic or anisotropic etch, decreasing the height of the conductive material below the height of the interlayer dielectric 104 to produce recessed conductive material 402. The reduced height of the conductive material in both sets of trenches may be set to a desired height of the eventual signal lines in the signal line trenches 204, as additional conductive material will be added later to the power lines to increase their height.

Referring now to FIG. 5, a cross-sectional view of a step in the fabrication of an integrated chip is shown. A dielectric cap 502 is conformally deposited over the recessed conductive material 402 using any appropriate conformal deposition, such as CVD or ALD. Because the signal line trenches 204 are narrower than the power line trenches 202, the deposition pinches off the opening above the signal line trenches 204, while a depression will be present over each power line trench 202. The depression follows the contour of the walls of the power line trench 202 and the top surface of the recessed conductive material 402 within the power line trench 202. To pinch off the material deposition in the opening of the signal line trenches 204, the dielectric cap 502 may be deposited to a thickness that is equal to one half of the width of the opening of the signal line trenches 204 or greater.

The dielectric cap 502 may be formed from any appropriate dielectric material that has appropriate etch selectivity with the recessed conductive material 402 and the interlayer dielectric 104. For example, silicon nitride may be used for the dielectric cap 502.

Referring now to FIG. 6, a cross-sectional view of a step in the fabrication of an integrated chip is shown. A selective isotropic etch is used to etch back the dielectric cap 502. Because the dielectric cap 502 pinched off over the signal line trenches 204, the dielectric material will be thicker in the regions of the narrower signal line trenches 204 than over the wider power line trenches 202. The isotropic etch can therefore be timed to completely remove the dielectric cap from over the power line trenches 202, while leaving signal line caps 602 in place, as the isotropic etch will remove material from all exposed surfaces above the power line trenches 202 equally, while only the horizontal top surface above the signal line trenches 204 is exposed. Etching back the dielectric cap 502 exposes the recessed conductive material 402 in the power line trenches 202.

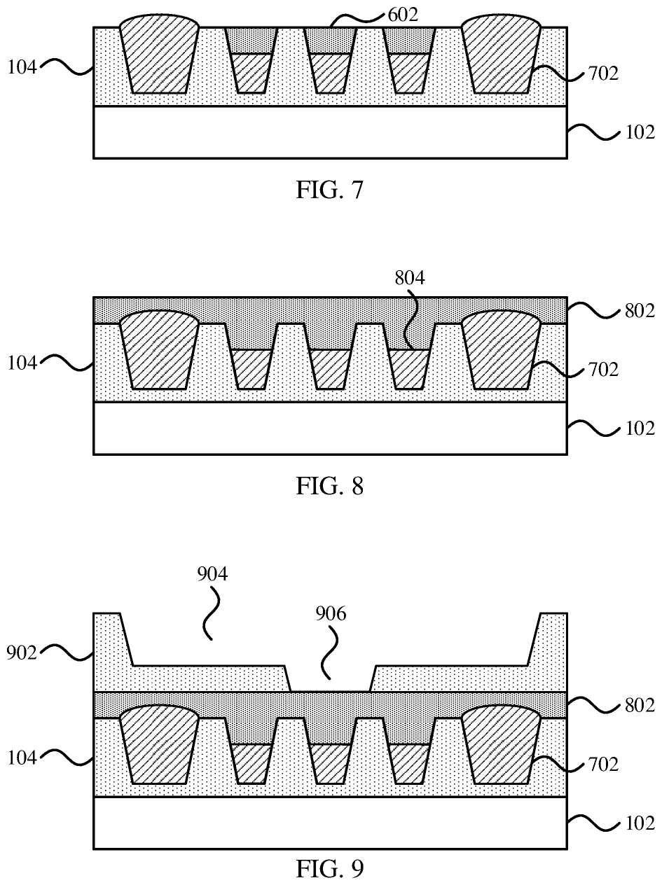

Referring now to FIG. 7, a cross-sectional view of a step in the fabrication of an integrated chip is shown. Additional conductive material is selectively deposited on the exposed conductive material 402 in the power line trenches 202, filling the power line trenches 202.

In some cases, the deposition of additional conductive material may be performed by a selective deposition of, e.g., cobalt, ruthenium, or tungsten on the underlying conductive material 402. In some cases the deposition of additional conductive material may be performed by a second damascene process that deposits additional conductive material by any appropriate deposition process (e.g., CVD, ALD, or PVD) and then polishing back with a CMP process.

The result of depositing the additional conductive material is to produce tall power lines 702 within the power line trenches 202, which in some cases may extend vertically past the height of the interlayer dielectric 104. The tall power lines 702 formed by selective deposition may have a curved top surface that extends to a height above a top surface of the signal line caps 602. In the latter case, the second damascene process may include the deposition of a second liner of barrier material (not shown).

The selective growth of metal may be performed using, e.g., CVD of cobalt, ruthenium, or tungsten. The deposited material will selectively adhere to the exposed metal surfaces and will not adhere to the exposed dielectric surfaces, resulting in a build-up of new conductive material over the original conductive material without accumulation elsewhere.

Referring now to FIG. 8, a cross-sectional view of a step in the fabrication of an integrated chip is shown. Additional dielectric cap material is deposited by any appropriate deposition process, such as CVD, ALD, or PVD, extending the signal line caps 602 to form dielectric cap 802 that covers the tall power lines 702 and the signal lines 804. The additional dielectric cap material may be the same as was used to form the original dielectric cap 502 (e.g., silicon nitride), or may be another dielectric material with appropriate etch selectivity, in particular with respect to the conductive material of the power lines 702 and the signal lines 804, as well as with respect to the interlayer dielectric 104.

The above-described process creates lines at two different widths and two different heights, including the relatively broad and tall power lines 702 and the relatively narrow and short signal lines 804. If this is the final metallization layer, then processing may be halted, and any final electrical contacts may be formed. However, any number of additional metallization layers may be formed above the dielectric cap 802.

An additional metallization layer may be formed over the lines, for example creating a network of signal communications and power distribution lines that can make any appropriate electrical connections that are needed for operation of the integrated chip. Because of the small spacing between adjacent features, for example between neighboring signal lines 804 or between a signal line 804 and a power line 702, the placement of vias between this layer and a next metallization layer has a need for high precision. A small placement error for such a via can cause a short-circuit between adjacent lines or breakdown of the dielectric material, and may impair the functioning of the device.

Referring now to FIG. 9, a cross-sectional view of a step in the fabrication of an integrated chip is shown. A new interlayer dielectric 902 is deposited over the dielectric cap 802 and is patterned to form a trench 904 with a via 906. The trench 904 may be oriented in a direction that is perpendicular to a direction along which the tall power lines 702 and the signal lines 804 extend.

Patterning the via 906 may be performed by a second patterning process, after the trench 904 has been formed, using a separate photolithographic mask to establish the location of the via 906. The positioning of the via 906 is selected to be located above the signal line 804 of interest, and the feature size of the via 906 may be roughly the same size as the width of the underlying signal line 804.

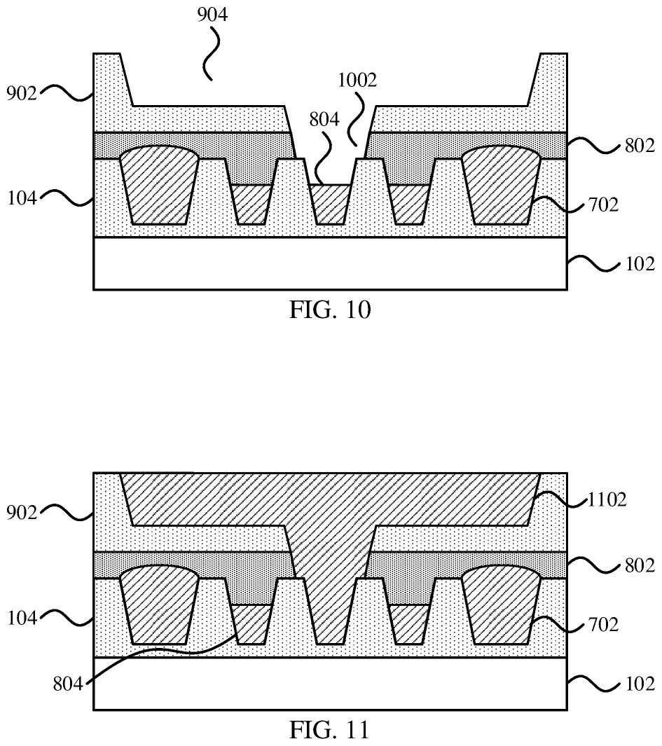

Referring now to FIG. 10, a cross-sectional view of a step in the fabrication of an integrated chip is shown. A selective anisotropic etch is used to extend the via 906 to create via 1002, exposing an underlying signal line 804. This via 1002 is shown as being fully aligned with one signal line 804, maximizing the distance between the via 1002 and neighboring signal lines 804 to maximize the amount of dielectric material between them.

Referring now to FIG. 11, a cross-sectional view of a step in the fabrication of an integrated chip is shown. Conductive material is deposited to fill the trench 904 and the via 1002, forming a metal line 1102 that extends down through the via 1002 down to contact the signal line 804. The metal line 1102 is part of an upper metallization layer that can provide signal communication between various layers and that can, with the addition of one or more additional vias to another signal line 804, provide lateral signal communication, for example to devices embedded in another region of the underlying layer 102.

The signal lines 804 have a smaller cross-sectional area than the power lines 702, and so will have a higher resistivity per unit length. However, because signal lines 804 may have much shorter run lengths than the power lines 702, the signal lines 804 may contribute much less to the total power losses of the device.

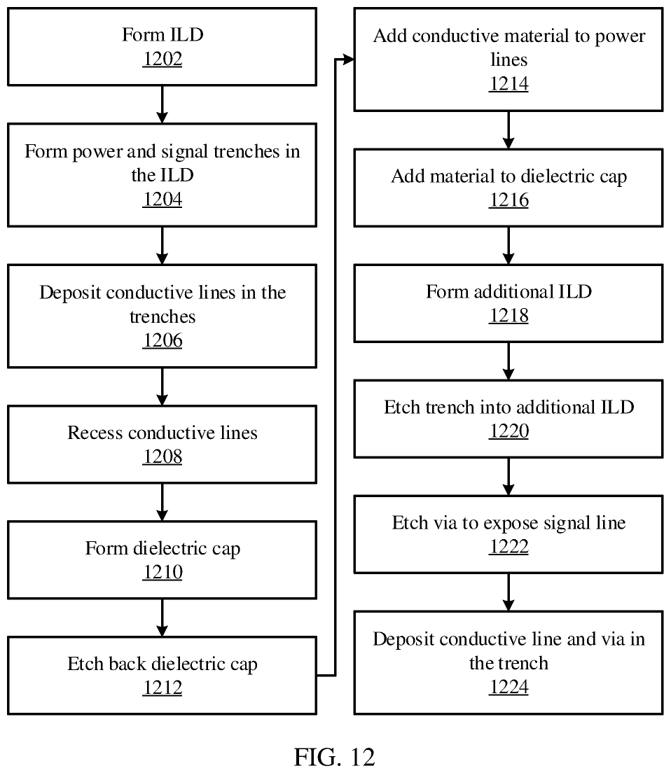

Referring now to FIG. 12, a method for forming an integrated chip is shown. Block 1202 forms an interlayer dielectric 104 over an underlying layer 102. The underlying layer 102 may be a semiconductor substrate or may be an entire wafer or chip with devices already formed therein. The interlayer dielectric 104 may be formed by any appropriate deposition process, such as CVD, ALD, PVD, or GCIB deposition, and may include any appropriate dielectric material, such as silicon dioxide.

Block 1204 forms power line trenches 202 and signal line trenches 204 in the interlayer dielectric 104, for example by forming a pattern mask using photolithography and then anisotropically and selectively etching down into the interlayer dielectric 104, for example using RIE. Block 1206 forms conductive material 302 in the trenches by depositing a conductive material using any appropriate deposition process and then polishing down to a top surface of the interlayer dielectric 104 using, e.g., a CMP process.

Block 1208 recesses the conductive material 302 below a height of the interlayer dielectric 104 using any appropriate isotropic or anisotropic etch. Block 1210 deposits a dielectric cap 502 over the conductive material 302 using a conformal deposition process, such as CVD or ALD. The deposition of the dielectric cap 502 pinches off the openings over the narrower signal line trenches 204, but retains a depression over the wider power line trenches 202.

Block 1212 etches back the dielectric cap 502 using an isotropic etch. Because the dielectric cap 502 pinched off the openings over the signal line trenches 204, the dielectric material is effectively thicker in those regions. The etch of block 1212 may be timed so that the dielectric cap material is removed entirely from above the power line trenches 202, while leaving at least a portion above the signal line trenches 204.

Block 1214 adds conductive material to form power lines 702. The formation of the tall power lines 702 may include a selective deposition of additional conductive material only in the regions of the power line trenches 202. The addition of conductive material may be performed using a second damascene process. Block 1216 adds material to the dielectric cap 802 to cover the tall power lines 702 using any appropriate deposition process.

If this is the final metallization layer, then processing may be halted. If additional metallization layers are desired, then block 1218 forms an additional interlayer dielectric 902 over the dielectric cap 802. Block 1220 etches trenches 904 into the additional interlayer dielectric 902, for example in an orientation that is perpendicular to the power lines 702 of the layer below. Block 1222 etches a via 1002 down through the additional interlayer dielectric 902 and through the dielectric cap 802, using one or more anisotropic etches, to expose a top surface of one of the signal lines 804. Block 1224 then deposits conductive material in the trench 904 and the via 1002 to form an electrical contact to the signal line 804.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative teams are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it ill also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of tall power lines with aligned signal vias (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A device, comprising:
a first conductive line having a top surface at a first height above an underlying layer;
a second conductive line, parallel to the first conductive line, having a second height above the underlying layer that is greater than the first height; and
a first interlayer dielectric layer, between the first conductive line and the second conductive line, having a top surface at a third height above the underlying layer that is greater than the first height and that is less than the second height.

2. The device of claim 1, wherein the second height is greater than the third height.

3. The device of claim 1, wherein a top surface of the second conductive line is curved.

4. The device of claim 1, further comprising a dielectric cap over the first conductive line and the second conductive line, having a top surface at a fourth height above the underling layer that is greater than the second height.

5. The device of claim 4, wherein the first interlayer dielectric layer is formed from a first dielectric material and the dielectric cap is formed from a second, different dielectric material.

6. The device of claim 4, further comprising a third conductive line over the first conductive line and the second conductive line oriented perpendicular relative to the first conductive line and the second conductive line.

7. The device of claim 6, further comprising a conductive via that extends through the dielectric cap to make electrical contact between the first conductive line and the third conductive line.

8. The device of claim 6, further comprising a second interlayer dielectric layer, between the dielectric cap and the third conductive line.

9. The device of claim 1, wherein the second conductive line is wider than the first conductive line.

10. The device of claim 1, wherein the first conductive line is a signal-carrying line and the second conductive line is a power-carrying line, with the signal-carrying line having a shorter length than the power-carrying line.

11. The device of claim 1, wherein the first conductive line and the second conductive line have respective bottom surfaces that have a same height above the underlying layer.

12. A device, comprising:
a first conductive line having first width and a top surface at a first height above an underlying layer;
a second conductive line, parallel to the first conductive line, having a second width that is greater than the first width and having a curved top surface with a second height above the underlying layer that is greater than the first height;
a first interlayer dielectric layer, formed from a first dielectric material, between the first conductive line and the second conductive line, having a top surface at a third height above the underlying layer that is between the first height and the second height;
a dielectric cap over the first conductive line, formed from a second dielectric material that is different from the first dielectric material, the second conductive line, and the first interlayer dielectric layer;
a third conductive line over the first conductive line and the second conductive line, oriented perpendicular relative to the first conductive line and the second conductive line;
a conductive via that extends through the dielectric cap to make electrical contact between the first conductive line and the third conductive line.

13. A method of forming a device, comprising:
etching a first trench and a second trench into a dielectric layer;
depositing a conductive material in the first trench and the second trench;
forming a dielectric cap over the first trench, leaving the second trench exposed; and
selectively depositing additional conductive material in the second trench.

14. The method of claim 13, wherein the second trench is wider than the first trench.

15. The method of claim 13, wherein forming the dielectric cap comprises:
depositing a dielectric material with a conformal deposition process that pinches off an opening of the first trench, but not the second trench; and
isotropically etching back the dielectric material to expose the conductive material in the second trench, leaving dielectric material in the first trench.

16. The method of claim 13, further comprising etching back the conductive material in the first trench and the second trench to a height below a top surface of the dielectric layer, before forming the dielectric cap.

17. The method of claim 13, further comprising depositing additional dielectric cap material over the dielectric cap and the additional conductive material.

18. The method of claim 17, further comprising etching a via through the dielectric cap and the additional dielectric cap material to expose the conductive material in the first trench and depositing a conductive material in the via.

19. The method of claim 13, wherein selectively depositing additional conductive material in the second trench comprises a selection deposition process that deposits metal on the conductive material in the second trench without depositing metal on top surfaces of the dielectric layer or dielectric cap.

20. The method of claim 13, wherein selectively depositing additional conductive material in the second trench comprises a damascene process that includes a deposition step and a polishing step.
